(19) United States
(12) Patent Application Publication
(10) Pub. No.: US 2026/0243855 A1
(43) Pub. Date: Aug. 20, 2026

(54) MAGNETIC FIELD SENSOR COMPRISING A SENSOR CIRCUIT BOARD

(71) Applicant: Robert Bosch GmbH, Stuttgart (DE)

(72) Inventors: Andreas Kugler, Alfdorf (DE); Julian Kassel, Pforzheim (DE); Kaja Schmidt, Stuttgart (DE)

(21) Appl. No.: 19/471,231

(22) PCT Filed: May 21, 2024
(86) PCT No.: PCT/EP2024/063883

§ 371 Date: Sep. 30, 2025

(30) Foreign Application Priority Data
Jun. 13, 2023 (DE) 10 2023 205 467.1

(51) Int. Cl. G01R 33/32; G01R 33/00; G01R 33/26; G01R 33/383

(52) U.S. Cl. CPC G01R 33/323; G01R 33/0005; G01R 33/0047; G01R 33/0052; G01R 33/26; G01R 33/383

(57) ABSTRACT

A magnetic field sensor with a microwave source and a sensor circuit board. The sensor circuit board includes a sensor crystal with at least one magneto-optical defect, an excitation light source, a detector, and at least two permanent magnets.

The sensor crystal is disposed such that microwave radiation generated by the microwave source can be absorbed by the at least one magneto-optical defect of the sensor crystal. The excitation light source is designed to emit an excitation light beam and is configured and disposed such that the excitation light beam emitted by the excitation light source can cause an emission of fluorescence radiation in the at least one magneto-optical defect of the sensor crystal. The detector is configured and disposed such that it detects the emitted fluorescence radiation. The permanent magnets are disposed and designed such that they generate a homogeneous static magnetic field in the sensor crystal.

### FIELD

The present invention relates to a magnetic field sensor based on a sensor circuit board and a method for producing such a magnetic field sensor.

### BACKGROUND INFORMATION

So-called NV magnetic field sensors are used to detect a magnetic field. These comprise a diamond, the crystal lattice of which has defects in the form of NV centers. In an NV center, a nitrogen atom occupies the lattice site of a carbon atom, and a vacancy is disposed in direct proximity to the nitrogen atom-again on the lattice site of a carbon atom. Irradiating such a crystal lattice with excitation radiation having a wavelength between 490 nm and 575 nm induces an electronic transition in the crystal lattice from a ground state ³A₂ to an excited state ³E. From the excited state ³E, the NV center relaxes back to the ground state ³A₂ with the emission of fluorescence radiation in a wavelength range between 650 nm and 750 nm. The ground state ³A₂ has three magnetic substates with mₛ=0 and mₛ=±1. The states with mₛ=0 and mₛ=±1 differ by an energy difference of 2.87 GHz (zero field splitting). The excited state ³E also has three magnetic substates with mₛ=0 and mₛ=±1. If the NV center in the ground state ³A₂ is now exposed to microwave radiation with a frequency of 2.87 GHz, the NV center oscillates between the mₛ=0, ³A₂ ground state and the mₛ=±1, ³A₂ ground state. Irradiation with the excitation radiation then partially shifts the NV center from the mₛ=±1, ³A₂ ground state to the excited mₛ=±1, ³E state. From there, it relaxes back to the ground state, largely without radiation. If the amplitude of the fluorescence radiation is measured as a function of the frequency of the microwave radiation, there is a sudden drop in the amplitude of the fluorescence radiation (a so-called dip) at a frequency of 2.87 GHz. The reason for the drop in the amplitude of the fluorescence radiation is that, when irradiated with microwave radiation having a frequency of 2.87 GHz, there are fewer NV centers in the mₛ=0, ³A₂ ground state that are available to be optically excited and that relax to the mₛ=±1, ³A₂ ground state while emitting fluorescence radiation.

In an external magnetic field, the mₛ=±1, ³A₂ ground state splits into two states with the spin quantum number mₛ=1 and mₛ=−1 (Zeemann effect). If the amplitude of the fluorescence radiation is then measured while changing the frequency of the microwave radiation, two dips are obtained. The frequencies at which these dips occur depend on the magnitude of the splitting of the mₛ=±1, ³A₂ ground state and thus on the field strength of the external magnetic field. This makes it possible to determine the field strength of an external magnetic field.

Such a magnetic field sensor is described in Germany Patent Application No. DE 10 2020 204 732, for example. The excitation radiation is generated here using a laser diode disposed in a cavity. The cavity is formed by a recess in a carrier wafer and a glass substrate that hermetically seals the cavity. The excitation radiation is directed through the glass substrate into an underlying plane in which it is focused onto an NV diamond. The lower plane comprises a substrate on which the remaining system components, such as the diamond, a high-frequency device, photodetectors and oher optical components, are disposed. The substrate is closed off with a cap substrate that comprises an opening through which the excitation radiation can reach the diamond.

### SUMMARY

The present invention relates to a magnetic field sensor and a method for producing a magnetic field sensor. Advantageous embodiments of the present invention are disclosed herein.

An example embodiment of the present invention in particular provides a magnetic field sensor with a microwave source and a sensor circuit board, wherein the sensor circuit board comprises a sensor crystal with at least one magneto-optical defect, an excitation light source, a detector and at least two permanent magnets. The sensor crystal and the microwave source are oriented relative to one another such that microwave radiation generated by the microwave source can be absorbed by the magneto-optical defect. The sensor crystal is preferably a diamond; the magneto-optical defect is an NV center. The excitation light source is designed to emit an excitation light beam and is configured and disposed such that the excitation light beam emitted by the excitation light source can cause an emission of fluorescence radiation in the at least one magneto-optical defect of the sensor crystal. The excitation light source is preferably a diode laser with a wavelength between 490 nm and 575 nm. The detector is configured and disposed such that it can detect the emitted fluorescence radiation and, for example, is configured as a photodiode that can detect radiation in a wavelength range of the fluorescence radiation, in particular between 650 nm and 750 nm. The at least two permanent magnets are disposed and designed such that a homogeneous static magnetic field is present in the sensor crystal. The excitation light source and the sensor crystal are in particular disposed directly or indirectly on an upper side of the sensor circuit board. The excitation light beam generated by the excitation light source can be focused via an optical element, in particular a lens, and directed onto the sensor crystal. The sensor crystal is preferably configured as a cube, plate or rod. A reference detector, which is in particular configured as a photodiode, can be disposed on or in the sensor circuit board in addition to the detector. The excitation light beam can be directed through the sensor crystal onto a deflection element that directs the excitation light beam to the reference detector. The provision of a reference detector makes it possible filter out fluctuations, for instance in the intensity of the excitation light source, from the signal measured at the detector. The detector is in particular disposed between the sensor crystal and the sensor circuit board. A filter element, which filters out radiation outside the wavelength range of the fluorescence radiation, can also be disposed between the sensor crystal and the detector. Such a filter element can also be disposed, viewed in the beam direction of the excitation light beam, in front of the reference detector. Such a filter element enables an improved signal-to-noise ratio of the fluorescence radiation and/or the excitation light beam detected at the detector and/or the reference detector. The microwave source can likewise be disposed on the upper side of the sensor circuit board or it can also be integrated into the sensor circuit board.

Such an arrangement of the components of a magnetic field sensor on or in a sensor circuit board enables a very compact and simple design, so that such a magnetic field sensor can be used in many different ways. Such an arrangement moreover makes it possible to fasten and bring into contact all of the components on or in the sensor circuit board by means of soldering, bonding and/or adhesive technologies, which means simple and cost-efficient manufacturing of the magnetic field sensor.

In one example embodiment of the present invention, the sensor circuit board of the magnetic field sensor comprises one or more inner layers and is thus configured as a multi-layer sensor circuit board. This enables an even more compact design of the magnetic field sensor, because individual components can also be disposed on the inner layer or layers of the sensor circuit board.

In a further embodiment of the present invention, the sensor circuit board of the magnetic field sensor comprises one or more recesses in which the detector and/or the reference detector are preferably disposed. The detector and/or the reference detector are in particular disposed in the recess or recesses and thus on the inner layer of the sensor circuit board. If the reference detector is disposed in the recess, the excitation light beam can be directed onto the reference detector via an optical element, e.g. a mirror, a prism or a beam splitter. This enables further miniaturization of the magnetic field sensor.

In a further embodiment of the present invention, the magnetic field sensor comprises one or more contact elements that are each electrically conductively connected to the detector and/or the reference detector and are disposed on the inner layer of the sensor circuit board. The detector and/or the reference detector are advantageously configured as a photodiode, particularly preferably as a surface-mounted device (SMD), wherein a detection region of the photodiode is opposite to a contact region of the photodiode. An interface for electrically contacting the photodiode is provided in the contact region. A sensitive surface suitable for detecting incident radiation is provided in the detection region. The photodiode is then in particular disposed on the inner layer of the sensor circuit board, in which case the contact region faces the inner layer of the sensor circuit board or rests on the inner layer. Because the detector is brought into contact via a contact element on the at least one inner layer, there is no need to dispose contact elements on the upper side of the sensor circuit board. This moreover enables the detector to be disposed horizontally, i.e. with its contact region facing the sensor circuit board, and not—as in the related art—vertically, i.e., with one of its narrow surfaces adjacent to the detection region and the contact region resting on the sensor circuit board, which results in an unstable arrangement requiring a large amount of space. Contacting the detector via a contact element disposed in the at least one inner layer thus enables a very compact design of the magnetic field sensor.

In a further embodiment of the present invention, the permanent magnets are disposed on the inner layer of the sensor circuit board which should in particular be laminated in. This then enables a space-saving arrangement of the permanent magnets.

In a further embodiment of the present invention, the permanent magnets are disposed on the upper side and/or an underside of the sensor circuit board. The permanent magnets are in particular disposed in a single-layer or multi-layer Halbach arrangement, so that a homogeneous permanent magnetic field is present in the sensor crystal. The individual permanent magnets can be disposed in a circle around the sensor crystal in the form of a cylindrical Halbach arrangement. Such a cylindrical Halbach arrangement consists of individual permanent magnets or segments of permanent magnets, the magnetization directions of which are tilted 90° relative to one another in the direction of the circular line of the cylindrical arrangement.

The magnetization directions of adjacent permanent magnets or segments can in principle also include an angle less than 90°, which results in an even more homogeneous field inside the cylindrical arrangement.

The permanent magnets can also be disposed in a straight line next to one another in a Halbach arrangement to create a rod-shaped arrangement of permanent magnets with a homogeneous static magnetic field on one of the sides of the rod-shaped arrangement and a vanishing magnetic field on the opposite side. Such a Halbach arrangement consists of individual permanent magnets or segments of permanent magnets, the magnetization directions of which are tilted 90° relative to one another in the direction of the longitudinal axis of the rod-shaped arrangement. The magnetization directions of adjacent permanent magnets or segments of permanent magnets can in principle include an angle less than 90° here as well, which makes the static magnetic field even more homogeneous. In this case, too, the sensor crystal is disposed in the homogeneous static magnetic field.

In the case of a two-layer Halbach arrangement, a first layer of permanent magnets can be disposed on the upper side and a second layer of permanent magnets can be disposed on the underside of the sensor circuit board. It is also possible to dispose a first layer of permanent magnets on the upper side, a second layer on the at least one inner layer and optionally a third layer of permanent magnets on the underside of the sensor circuit board. If the sensor circuit board comprises multiple inner layers, layers of permanent magnets can be disposed on each of the inner layers or even only on a portion of the inner layers. In the case of a cylindrical Halbach arrangement, the individual cylindrically configured layers can be disposed one above the other such that they have the same cylinder axis and in particular also the same cylinder radius. This enables a very compact design of the magnetic field sensor, while at the same time creating a very homogeneous magnetic field in the region of the sensor crystal.

In one embodiment of the present invention, a respective first heat sink is disposed on the upper side and/or on the at least one inner layer of the sensor circuit board, in particular in the region below the excitation light source. It can be connected to the underside of the sensor circuit board by means of one or more vias. The heat sink is in particular configured as a metal surface, for example as a metal surface made of copper or comprising copper components. The heat sink can comprise a coating, for example made of gold. The heat sink can be connected to the underside of the sensor circuit board by means of one or more vias. The vias can contain a metal, be filled with a metal, or consist of a metal.

A second heat sink, which is preferably connected to the vias, can be disposed on the underside of the sensor circuit board. The second heat sink can be configured as a metal surface, for example made of copper, aluminum or comprising copper or aluminum components. The heat sink can in particular be formed by laminating a metal surface made of aluminum onto another surface. The first and/or the second heat sink can have a thickness between 33 μm and 300 μm thick and can be made of copper, for example. This enables efficient dissipation of the heat created by the operation of the excitation light source.

The sensor circuit board can also include one or more inner layers made of metal or comprising metal components in a region below the excitation light source. Alternatively, only portions of the inner layer or inner layers disposed in the region below the excitation light source, in particular those with as large a surface area as possible, can be made of metal or comprise metal components. This prevents moisture entering the region of the excitation light source.

In a further embodiment of the present invention, the magnetic field sensor can comprise a protective hood which is disposed on the sensor circuit board such that at least the excitation light source and the detector are completely enclosed. The height of the protective hood be less than 5 mm, in particular less than 1 mm. The width of the protective hood can also be 5 mm, in particular less than 1 mm. This ensures that the volume below the protective hood is as small as possible.

The protective hood can be made of a non-magnetic metal, for example copper. The protective hood can also be made of a metallized plastic or another electrically conductive material. Metal surfaces can be provided below the protective hood on the upper side or in the sensor circuit board. In this region, the sensor circuit board can also contain a small amount of a plastic material, for example a polychlorinated biphenyl or a thermoset.

This ensures quasi-hermetic protection of the excitation light source and—during operation of the excitation light source—also of the excitation light beam propagating freely in the magnetic field sensor against interference.

In one embodiment of the present invention, the magnetic field sensor is completely encased in a plastic material. The magnetic field sensor can alternatively also be encased in the plastic material only on its upper side, so that the underside of the sensor circuit board is not encased. The plastic material can be a thermoplastic or thermosetting material. Encasing, in particular with a thermosetting material, makes the magnetic field sensor only slightly heavier and provides optimum protection from its surroundings.

In particular when the magnetic field sensor is completely encased, a contact element, for example a plug, can be part of this encasement.

The encasement provides cost-effective packaging for the magnetic field sensor and protects it from environmental influences and damage. This ensures reliable operation of the magnetic field sensor, even outside the laboratory.

Complete encasement is particularly advantageous if a portion of the permanent magnets is disposed on the underside of the sensor circuit board, as the complete encasement also protects these permanent magnets from damage and environmental influences.

Electronic components, in particular circuits necessary for the operation of the magnetic field sensor, can be fastened to the sensor circuit board as open semiconductors and/or surface-mounted device (SMD) components. SMD components are components that can be attached to a surface. The electronic components can also be integrated into unpackaged semiconductors and/or into one or more ASIC semiconductors and can be brought into electrical contact via a chip-on-board or flip chip technology, for example. This enables a very compact design of the magnetic field sensor.

The magnetic field sensor can be provided with solder contacts on its underside, so that the magnetic field sensor can be soldered to a further circuit board, for example. The magnetic field sensor can also comprise bump-like contacts, solder contact surfaces and/or plug connectors for contacting the sensor circuit board, in which case the latter are soldered to the sensor circuit board using SMD technology, for example.

An HF suitable substrate can be disposed on the sensor circuit board of the magnetic field sensor. The sensor circuit board can alternatively also consist at least partly of an HF suitable substrate. The microwave source or a microwave coupling device is thus disposed on the upper side or integrated into the sensor circuit board, which results in a particularly compact design of the magnetic field sensor.

The present invention further comprises a method for producing a magnetic field sensor. First, a sensor circuit board is produced as a multi-layer sensor circuit board comprising one or more inner layers or as a single-layer sensor circuit board. The sensor circuit board is produced using thin film technology, for example, or as a printed circuit board (PCB). The sensor circuit board is in particular produced comprising one or more receptacles for later accommodating one or more detectors and/or one or more heat sinks and/or metal layers and/or vias. If the sensor circuit board is produced as a multi-layer sensor circuit board, one inner layer can be fitted with at least two permanent magnets such that a homogeneous static magnetic field can be generated in the sensor crystal. For this purpose, a first or a first group of permanent magnets is disposed on and fastened to the inner layer of the sensor circuit board and then a second or a second group of permanent magnets is disposed on and fastened to the inner layer of the sensor circuit board. The inner layer fitted with the permanent magnets can then be mechanically connected to an upper side and an underside of the sensor circuit board, for example by means of lamination. The inner layer of the sensor circuit board is in particular fitted with the permanent magnets during production of the sensor circuit board and is then laminated.

After production, the sensor circuit board is fitted with an excitation light source, at least one detector and a sensor crystal such that an excitation light beam generated by the excitation light source can cause an emission of fluorescence radiation in the sensor crystal and the detector can detect the fluorescence radiation. The detector and/or the reference detector are preferably configured as a surface-mounted device (SMD), or can be fastened to the upper side or an inner layer of the sensor circuit board using SMD technology, in particular by soldering or conductive gluing.

After fitting the sensor circuit board with the excitation light source, the detector or detectors and the sensor crystal, the upper side and/or the underside of the sensor circuit board can be fitted with the permanent magnets. For this purpose, a first or a first group of permanent magnets can be disposed on and fastened to the upper side and/or underside of the sensor circuit board and then a second or a second group of permanent magnets can be disposed on and fastened to the upper side and/or the underside of the sensor circuit board. The advantage of this is that the permanent magnets can be fastened in a defined position relative to the sensor crystal. This ensures that a homogeneous magnetic field is present in the sensor crystal.

This in particular prevents the permanent magnets from changing their position during the fitting process due to their mutual interaction. The excitation light source, the sensor crystal, the detector or detectors and the permanent magnets are fitted onto specific reference marks on the sensor circuit board, so that any etching tolerances that may occur during the etching of the circuit board can be taken into account. Special tools, e.g. so-called die collets, can be used to prevent the permanent magnets from slipping during fitting. To prevent the permanent magnets from slipping during fitting, it is also possible to use fast curing adhesives, which cure as a result of heat or radiation, to secure the permanent magnets during fitting.

A protective hood can furthermore be fastened to the upper side of the sensor circuit board, in particular by means of gluing, plugging or soldering, so that at least the excitation light source and the detector are completely enclosed. Particularly good sealing of the magnetic field sensor against its surroundings is achieved by soldering the protective hood onto the upper side of the sensor circuit board, in particular using a high-melting solder, so that already existing solder contacts do not melt again during subsequent further processing.

The sensor circuit board can be fitted with electronic components, in particular circuits. These can be integrated into one or more ASIC semiconductors and can be bonded to the sensor circuit board as open semiconductors, for example.

A chip-on-board process (e.g., die attach and/or wire bonding) or a flip chip process can be used for this purpose.

The sensor circuit board fitted with the excitation light source, the at least one detector and the sensor crystal can furthermore be encased in a plastic material, in particular a thermoplastic or a thermosetting plastic material. Overmolding can be carried out with a single or a multiple tool.

The fitted sensor circuit boards can be individually back injection molded using a molding process, for example an in-mold process. The fitted sensor circuit boards can alternatively also be back injection molded in a circuit board panel, for example using a casting process such as the process described in Germany Patent Application No. DE 10 2017 216 711 A1. These processes make it possible to use materials that, due to their ionic purity and flowability, enable the use of packaged components, passive SMDs, open semiconductor components or so-called bare dies to accommodate the assemblies needed for the functioning of the magnetic field sensor.

If a chip-on-board process (e.g., die attach and/or wire bonding) or a flip chip process is used to fasten an open semiconductor to the sensor circuit board, for example, a molding process or a low-pressure molding (LPM) process is a suitable method for applying the plastic in the case of chip-on-board technology, and in the case of flip chip technology, the DIM process is possible as well.

The individual sensor circuit boards can then be singulated using dicing processes, which enables very cost-effective mass production in particular for very small sensor circuit boards.

The sensor circuit board can be encased completely or only on the upper side. In the latter case, solder contacts can be applied to the exposed underside of the sensor circuit board.

This can be done before or after the assemblies are singulated, during production of the sensor circuit board, during fitting, or after the sensor circuit board is encased.

Further advantages and embodiments of the present invention will emerge from the description and the accompanying drawing.

The present invention is illustrated schematically in the drawing on the basis of embodiment examples and is described in detail in the following with reference to the figures.

### BRIEF DESCRIPTION OF THE DRAWINGS

FIG. 1 shows a magnetic field sensor, in which a plurality of permanent magnets are respectively disposed on an upper side and an underside of a sensor circuit board, according to an example embodiment of the present invention.

FIG. 2 shows a magnetic field sensor, in which a plurality of permanent magnets are disposed on an inner layer of a sensor circuit board, according to an example embodiment of the present invention.

FIG. 3 shows a magnetic field sensor, in which a plurality of permanent magnets are disposed on an inner layer of a sensor circuit board and a protective hood is attached to the upper side of the sensor circuit board, according to an example embodiment of the present invention.

FIG. 4 shows a completely encased magnetic field sensor, according to an example embodiment of the present invention.

FIG. 5 shows a magnetic field sensor which is encased only on the upper side of the sensor circuit board, according to an example embodiment of the present invention.

### DETAILED DESCRIPTION OF EXAMPLE EMBODIMENTS

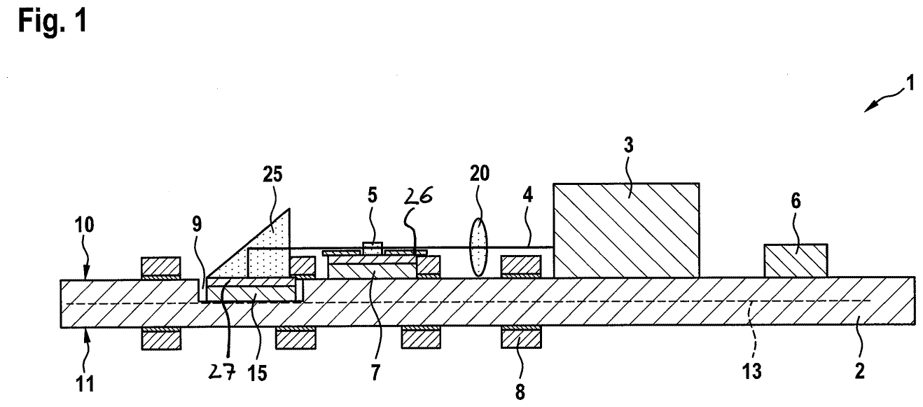

FIG. 1 shows a magnetic field sensor 1 comprising a sensor circuit board 2. An excitation light source 3, a sensor crystal 5, a detector 7 and permanent magnets 8 are disposed on an upper side 10 of the sensor circuit board 2. A filter element 26 is disposed between the detector 7 and the sensor crystal 5. Permanent magnets 8 are also disposed on the underside 11 of the sensor circuit board 2 The sensor crystal 5 is disposed on the upper side of the detector 7 and thus such that the detection region of the detector 7 faces one of the surfaces of the cuboid or cube-shaped sensor crystal 5. The sensor crystal 5 is embodied as a diamond and has at least one magneto-optical defect in the form of an NV center. The permanent magnets 8 are disposed in a circular or rod-shaped Halbach arrangement on both the underside 11 and the upper side 10 of the sensor circuit board 2 such that a homogeneous static magnetic field is present in the region of the sensor crystal 5. The excitation light source 3 is configured to generate an excitation light beam 4, which is guided through the sensor crystal 5 via a lens 20 onto a prism 25. At the prism 25, the excitation light beam 4 is deflected onto a reference detector 15. A further filter element 27 is disposed between the reference detector 15 and the prism. The reference detector 15 is disposed in a recess 9 and is thus disposed on an inner layer 13 of the sensor circuit board 2. A microwave source 6 is disposed on the upper side 10 of the sensor circuit board 2 such that microwave radiation generated by the microwave source 6 can be absorbed by the magneto-optical defect of the sensor crystal 5.

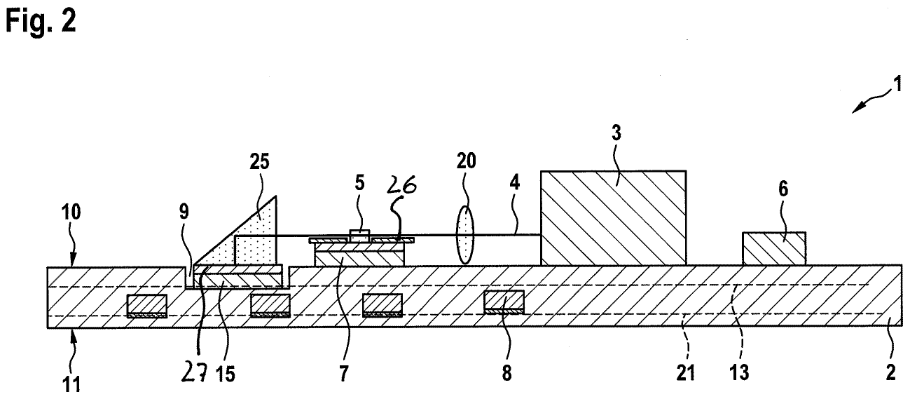

The magnetic field sensor 1 shown in FIG. 2 corresponds to the magnetic field sensor 1 shown in FIG. 1 with the difference that the permanent magnets 8 are not disposed on the upper side or underside of the sensor circuit board 2, but instead on an inner layer 13, 21 of the sensor circuit board 2.

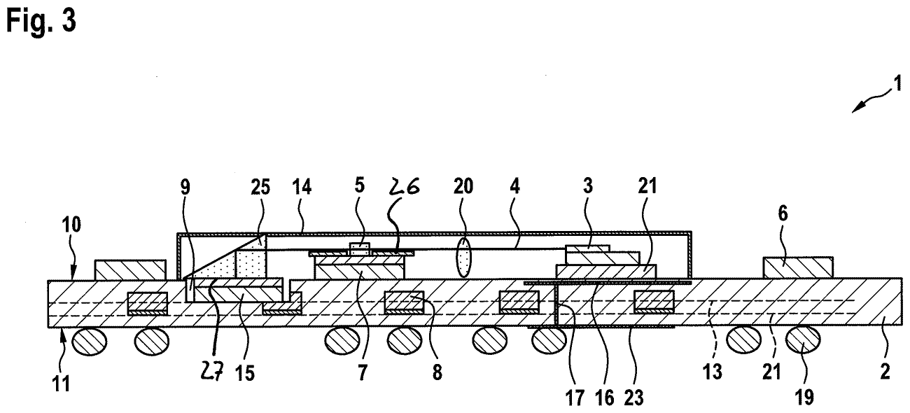

The magnetic field sensor 1 shown in FIG. 3 corresponds to the magnetic field sensor 1 shown in FIG. 2 with the difference that a protective hood 14 is attached to the upper side 10 of the sensor circuit board 2, wherein the excitation light source 3, the sensor crystal 5, the detector 7 and the reference detector 15 are disposed below the protective hood 14. Solder contacts 19, with which the sensor circuit board 2 can be attached to another circuit board, are attached to the underside 11 of the sensor circuit board 2. The microwave source 6 is also disposed on the upper side 10 of the sensor circuit board 2. The excitation light source 3 is disposed on a base 22, in which the electronic components needed for the operation of the excitation light source 3 are housed. A first heat sink 16, which is configured to absorb heat created in the operation of the excitation light source, is disposed below the excitation light source 3. The first heat sink 16 is configured as a metal surface and is connected by means of a via 17 to a second heat sink 23, which is disposed on the underside 11 of the sensor circuit board 2 and is likewise configured as a metal surface.

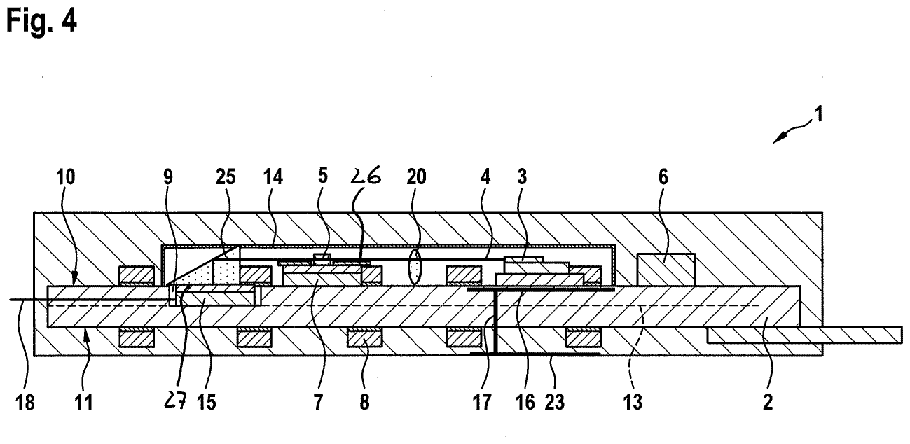

The magnetic field sensor 1 shown in FIG. 4 corresponds to the magnetic field sensor 1 shown in FIG. 1 with the difference that the magnetic field sensor 1 is completely encased in a plastic material. A first heat sink 16, which is configured to absorb heat created in the operation of the excitation light source, is disposed below the excitation light source 3. The first heat sink 16 is configured as a metal surface and is connected by means of a via 17 to a second heat sink 23, which is disposed on the underside 11 of the sensor circuit board 2 and is likewise configured as a metal surface.

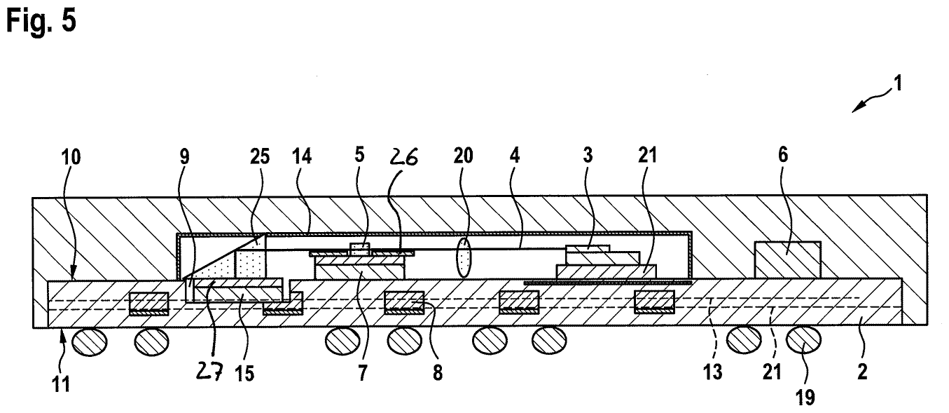

The magnetic field sensor 1 shown in FIG. 5 corresponds to the magnetic field sensor 1 shown in FIG. 3 with the difference that only the upper side 10 of the sensor circuit board 2 is encased in a plastic material.

1-15. (canceled)

16. A magnetic field sensor, comprising:
a microwave source; and
a sensor circuit board, wherein the sensor circuit board includes:
a sensor crystal with at least one magneto-optical defect, wherein the sensor crystal is disposed such that microwave radiation generated by the microwave source can be absorbed by the at least one magneto-optical defect of the sensor crystal,
an excitation light source configured to emit an excitation light beam and is configured and disposed such that the excitation light beam emitted by the excitation light source can cause an emission of fluorescence radiation in the at least one magneto-optical defect of the sensor crystal,
a detector which is configured and disposed such that the detector detects the emitted fluorescence radiation, and
and at least two permanent magnets which are disposed and configured such that the at least two permanent magnets generate a homogeneous static magnetic field in the sensor crystal.

17. The magnetic field sensor according to claim 16, wherein the sensor circuit board includes at least one inner layer.

18. The magnetic field sensor according to claim 16, wherein the sensor circuit board includes a recess in which the detector and/or a reference detector is disposed.

19. The magnetic field sensor according to claim 18, further comprising one or more contact elements that are each electrically conductively connected to the detector and/or the reference detector and are disposed in an inner layer of the sensor circuit board.

20. The magnetic field sensor according to claim 17, wherein the at least two permanent magnets are disposed on the inner layer of the sensor circuit board.

21. THe magnetic field sensor according to claim 16, wherein the sensor circuit board includes an upper side and an underside, and the at least two permanent magnets are disposed on the upper side and/or the underside of the sensor circuit board.

22. The magnetic field sensor according to claim 21, wherein a respective first heat sink including a first metal surface is disposed on the upper side and/or on at least one inner layer of the sensor circuit board, in a region of the excitation light source, which is connected to the underside of the sensor circuit board by one or more vias.

23. The magnetic field sensor according to claim 22, wherein a second heat sink which is connected to the vias is disposed on the underside of the sensor circuit board.

24. The magnetic field sensor according to claim 16, further comprising a protective hood which is configured such that the protective hood is electrically conductive and is disposed on the sensor circuit board such that at least the excitation light source, the detector, and the sensor crystal are completely enclosed.

25. The magnetic field sensor according to claim 24, wherein the magnetic field sensor is completely encased in a plastic material, including a thermoplastic or thermosetting material.

26. The magnetic field sensor according to claim 16, wherein an HF suitable substrate is disposed on the sensor circuit board or the sensor circuit board includes in part an HF suitable substrate.

27. A method for producing a magnetic field sensor, comprising the following steps:
producing a sensor circuit board;
fitting the sensor circuit board with an excitation light source, at least one detector, and a sensor crystal such that an excitation light beam generated by the excitation light source can cause an emission of fluorescence radiation in the sensor crystal and the detector can detect the fluorescence radiation; and
fitting an inner layer and/or an underside and/or an upper side surface of the sensor circuit board with at least two permanent magnets in such a way that a homogeneous static magnetic field can be generated in the sensor crystal, wherein a first or a first group of the permanent magnets are first disposed on and fastened to the inner layer and/or an underside and/or an upper side of the sensor circuit board, then a second or a second group of the permanent magnets are disposed on and fastened to the inner layer and/or the underside and/or the upper side of the sensor circuit board, and when the inner layer of the sensor circuit board has been fitted with permanent magnets, connecting the inner layer fitted with permanent magnets to the upper and the underside of the sensor circuit board, by lamination.

28. The method according to claim 27, wherein the fitting of the inner layer with permanent magnets and connecting the inner layer fitted with permanent magnets to the upper and the underside of the sensor circuit board takes place during production of the sensor circuit board.

29. The method according to claim 27, wherein a protective hood is fastened to the sensor circuit board by gluing or plugging or soldering, so that the excitation light source and the detector are completely enclosed.

30. The method according to claim 27, wherein the sensor circuit board fitted with the excitation light source, the at least one detector, and the sensor crystal is encased in a plastic material including a thermoplastic or a thermosetting material.
